(19) United States
(12) Patent Application Publication
(10) Pub. No.: US 2015/0128856 A1
(43) Pub. Date: May 14, 2015

(54) DISPENSING APPARATUS HAVING TRANSPORT SYSTEM AND METHOD FOR TRANSPORTING A SUBSTRATE WITHIN THE DISPENSING APPARATUS

(71) Applicant: Illinois Tool Works Inc., Glenview, IL (US)

(72) Inventors: Dennis G. Doyle, Shrewsbury, MA (US); Thomas E. Robinson, Walpole, MA (US)

(73) Assignee: Illinois Tool Works Inc., Glenview, IL (US)

(21) Appl. No.: 14/080,174

(22) Filed: Nov. 14, 2013

(51) Int. Cl. H01L 21/677; B05C 13/00

(52) U.S. Cl. CPC H01L 21/677; B05C 13/00
USPC 118/503; 414/222.01; 414/806

(57) ABSTRACT

A dispenser, which is configured to dispense viscous material on a substrate, includes a frame, a gantry system coupled to the frame, and a dispensing unit coupled to the gantry system. The gantry system is configured to move the dispensing unit in x-axis, y-axis, and z-axis directions. The dispenser further includes a substrate support assembly coupled to the frame and configured to support the substrate to dispense material on the substrate in a dispense position, and a transport system configured to transport the substrate to the dispense position and to remove the substrate from the dispense position. The transport system includes a first pusher assembly configured to move the substrate within the dispenser. A transport system and methods of dispensing material on a substrate are further disclosed.

### RELATED APPLICATION

This application relates to U.S. patent application Ser. No. ______ entitled DISPENSING APPARATUS HAVING SUBSTRATE INVERTER SYSTEM AND CLAMPING SYSTEM, AND METHOD FOR DISPENSING A VISCOUS MATERIAL ON A SUBSTRATE (Attorney Docket No. C2013-731719), by Dennis G. Doyle and Thomas E. Robinson, filed on even date herewith, and U.S. patent application Ser. No. ______ entitled DISPENSING APPARATUS HAVING SUBSTRATE INVERTER SYSTEM AND ROLLER SYSTEM, AND METHOD FOR DISPENSING A VISCOUS MATERIAL ON A SUBSTRATE (Attorney Docket No. C2013-731819), by Dennis G. Doyle, filed on even date herewith. All of these related applications are incorporated herein by reference.

### BACKGROUND OF THE DISCLOSURE

1. Field of the Invention

The invention relates generally to methods and apparatus for dispensing a viscous material on a substrate, such as a printed circuit substrate.

2. Discussion of Related Art

There are several types of prior art dispensing systems or dispensers used for dispensing metered amounts of liquid or paste for a variety of applications. One such application is the assembly of integrated circuit chips and other electronic components onto circuit board substrates. In this application, automated dispensing systems are used for dispensing dots of liquid epoxy or solder paste, or some other related material, onto circuit boards. Automated dispensing systems are also used for dispensing lines of underfill materials and encapsulents, which mechanically secure components to the circuit board. Underfill materials and encapsulents are used to improve the mechanical and environmental characteristics of the assembly.

FIG. 1 schematically illustrates a known dispenser, which is generally indicated at 10. The dispenser 10 is used to dispense a viscous material (e.g., an adhesive, encapsulent, epoxy, solder paste, underfill material, etc.) or a semi-viscous material (e.g., soldering flux, etc.) onto an electronic substrate 12, such as a printed circuit board or semiconductor wafer. The dispenser 10 may alternatively be used in other applications, such as for applying automotive gasketing material or in certain medical applications. It should be understood that references to viscous or semi-viscous materials, as used herein, are exemplary and intended to be non-limiting. In one embodiment, the dispenser 10 includes first and second dispensing units or heads, generally indicated at 14 and 16, respectively, and a controller 18 to control the operation of the dispenser. Although two dispensing units are shown, it should be understood that one or more dispensing units may be provided.

The dispenser 10 may also include a frame 20 having a base or support 22 for supporting the substrate 12, a dispensing unit gantry 24 movably coupled to the frame 20 for supporting and moving the dispensing units 14, 16, and a weight measurement device or weigh scale 26 for weighing dispensed quantities of the viscous material, for example, as part of a calibration procedure, and providing weight data to the controller 18. A conveyor system (not shown) or other transfer mechanism, such as a walking beam, may be used in the dispenser 10 to control loading and unloading of substrates to and from the dispenser. The gantry 24 can be moved using motors under the control of the controller 18 to position the dispensing units 14, 16 at predetermined locations over the substrate. The dispenser 10 may include a display unit 28 connected to the controller 18 for displaying various information to an operator. There may be an optional second controller for controlling the dispensing units.

Prior to performing a dispensing operation, as described above, the substrate, e.g., the printed circuit board, must be aligned or otherwise in registration with a dispensing unit of the dispenser. The dispenser further includes a vision system 30, which is coupled to a vision system gantry 32 movably coupled to the frame 20 for supporting and moving the vision system. Although shown separately from the dispensing unit gantry 24, the vision system gantry 32 may utilize the same gantry system as the dispensing units 14, 16. As described, the vision system 30 is employed to verify the location of landmarks, known as fiducials or other features and components, on the substrate. Once located, the controller can be programmed to manipulate the movement of one or both of the dispensing units 14, 16 to dispense material on the electronic substrate. The dispense operation may be controlled by the controller 18, which may include a computer system configured to control material dispensers. In another embodiment, the controller 18 may be manipulated by an operator.

In some embodiments, the dispenser 10 may operate as follows. The circuit board may be loaded into the dispenser 10 in a depositing position using the conveyor system. The circuit board is aligned with the dispensing units 14, 16 by using the vision system 30. The dispensing units 14, 16 may then be initiated by the controller 18 to perform a deposit operation in which material is deposited at precise locations on the circuit board. Once the dispensing units 14, 16 have performed a depositing operation, the circuit board may be transported by the conveyor system from the dispenser 10 so that a second, subsequent circuit board may be loaded into the material deposition system. The dispensing units 14, 16 may be constructed to be quickly removed and replaced with other units. The dispenser 10 is capable of dispensing material on only one side of the circuit board.

Sometimes, it is desirable to dispense such materials on both sides of the substrate. One such dispenser is offered by Protec Co., Ltd of Incheon, Korea, and incorporates a substrate support that rotates about an axis that is transverse to a direction that the substrate travels through the dispenser. With this dispenser, belts that engage edges of the substrate move the substrate through the dispenser. With this arrangement, it is difficult to dispense material near edges of the substrate since the belts interfere with the dispensing unit when attempting to dispense material near the edges of the substrate.

### SUMMARY OF THE DISCLOSURE

One aspect of the disclosure is directed to a dispenser for dispensing viscous material on a substrate. In one embodiment, the dispenser comprises a frame, a gantry system coupled to the frame, and a dispensing unit coupled to the gantry system. The gantry system is configured to move the dispensing unit in x-axis, y-axis, and z-axis directions. The dispenser further comprises a substrate support assembly coupled to the frame and configured to support the substrate to dispense material on the substrate in a dispense position, and a transport system configured to transport the substrate to the dispense position and to remove the substrate from the dispense position. The transport system includes a first pusher assembly configured to move the substrate within the dispenser.

Embodiments of the dispenser also may include providing a first belt assembly configured to operate with the first pusher assembly to move the substrate to the dispense position. The first belt assembly may include a first belt configured to engage an edge of the substrate, a second belt configured to engage an opposite edge of the substrate, and at least one motor configured to drive the rotation of the first belt and the second belt. The transport system further may include a second pusher assembly to move the substrate. Each of the first pusher assembly and the second pusher assembly may include a pusher member configured to engage an edge of the substrate, a linear bearing configured to guide a linear movement of the pusher member, and a motor configured to move the pusher member. Each of the first pusher assembly and the second pusher assembly may be synchronized with a respective belt assembly to maintain a constant velocity during delivery of the substrate to and from the dispense position.

Another aspect of the disclosure is transport system for a dispenser for dispensing viscous material on a substrate. The transport system being configured to transport the substrate to a dispense position of the dispenser and to remove the substrate from the dispense position. In one embodiment, the transport system comprises at least one pusher assembly configured to move the substrate within the dispenser.

Embodiments of the transport system further may include a first belt assembly configured to operate with the first pusher assembly to move the substrate to the dispense position. The first belt assembly may include a first belt configured to engage an edge of the substrate, a second belt configured to engage an opposite edge of the substrate, and at least one first motor configured to drive the rotation of the first belt and the second belt. The transport system further may include a second pusher assembly configured to move the substrate. Each of the first pusher assembly and the second pusher assembly may include a pusher member configured to engage an edge of the substrate, a linear bearing configured to guide a linear movement of the pusher member, and a motor configured to move the pusher member. Each of the first pusher assembly and the second pusher assembly may be synchronized with a respective belt assembly to maintain a constant velocity during delivery of the substrate to the dispense position.

Yet another aspect of the disclosure is directed to a method of transporting a substrate within a dispenser. In one embodiment, the method comprises moving the substrate to a dispense position of the dispenser with a first pusher assembly configured to move the substrate.

Embodiments of the method further may include engaging a first belt assembly with the substrate. Engaging the first belt assembly with the substrate further may include engaging a first belt with an edge of the substrate, and engaging a second belt with an opposite edge of the substrate. The method further may include driving the rotation of the first belt and the second belt with at least one first motor. The method further may include moving the substrate from the dispense position with a second pusher assembly configured to move the substrate. Each of the first pusher assembly and the second pusher assembly may be synchronized with a respective belt assembly to maintain a constant velocity during delivery of the substrate to the dispense position.

### BRIEF DESCRIPTION OF THE DRAWINGS

For a better understanding of the disclosure, reference is made to the figures which are incorporated herein by reference and in which:

FIG. 1 is a schematic view of a prior art dispenser;

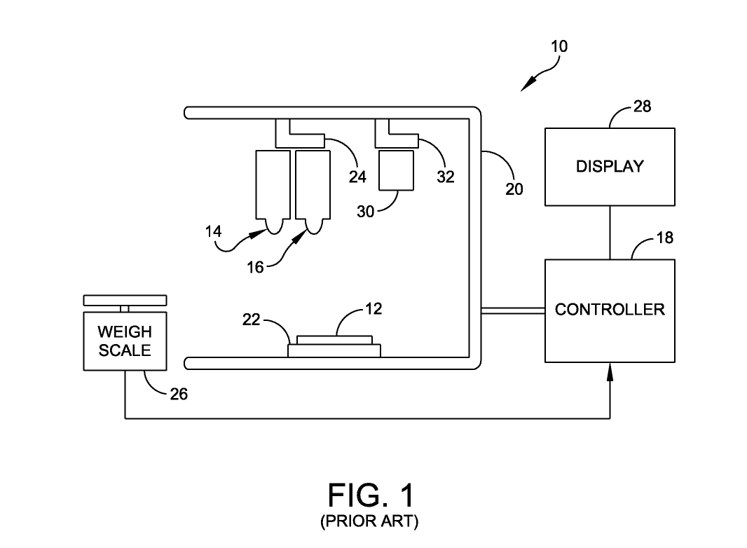

FIG. 2 is a partial top perspective view of a dispenser of an embodiment of the present disclosure with portions removed to better illustrate a transport system of the dispenser;

FIG. 3 is a top plan view of the dispenser shown in FIG. 2;

FIG. 4 is an enlarged partial perspective view of the dispenser having certain components of the dispenser removed to illustrate various aspects of the embodiment;

FIG. 5 is another enlarged partial perspective view of the dispenser taken from the rear of the dispenser having certain components of the dispenser removed to illustrate various aspects of the embodiment;

FIG. 6 is another enlarged partial perspective view of the dispenser having certain components of the dispenser removed to illustrate various aspects of the embodiment;

FIG. 7 is another enlarged partial perspective view of the dispenser having certain components of the dispenser removed to illustrate various aspects of the embodiment; and

FIG. 8 is an enlarged partial bottom perspective view of the dispenser.

### DETAILED DESCRIPTION OF THE PREFERRED EMBODIMENTS

For the purposes of illustration only, and not to limit the generality, the disclosure will now be described in detail with reference to the accompanying figures. This disclosure is not limited in its application to the details of construction and the arrangement of components set forth in the following description or illustrated in the drawings. The disclosure is capable of other embodiments and of being practiced or being carried out in various ways. Also the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

For purposes of illustration, embodiments of the present disclosure are described below, with reference to a dispenser used to dispense solder paste onto a circuit board. The apparatus and associated methods may also be used in other applications requiring dispensing of other viscous or dispensing materials, such as glues, adhesives, and encapsulants on a variety of substrates. For example, the apparatus may be used to dispense epoxy for use as underfill for chip-scale packages. In certain embodiments, the dispensing units may be of the type offered by Speedline Technologies, Inc. of Franklin, Mass.

This present disclosure is directed to a dispenser including a substrate support assembly having an inverter system provided within the dispenser, the inverter system being designed to engage the substrate without interfering with a dispensing unit when dispensing material near edges of the substrate. The dispenser disclosed herein is capable of inverting the substrate, thereby enabling the dispensing unit to dispense material on both sides of the substrate within five millimeters (mm) from the edge of the substrate with an auger-type dispensing unit and within eight mm from the edge of the substrate with a jetter-type dispensing unit. Since traditional transport belts interfere with the dispensing unit in the space above the substrate, the dispenser, in one embodiment, includes a clamping system to hold the substrate when in the dispense position. To deliver the substrate to a dispense position within the dispenser, the dispenser includes a combination of substrate pushers and belts since belts alone cannot completely transport the substrate onto or off of the clamping system of the substrate support assembly. In another embodiment, the substrate support assembly of the dispenser includes a roller system along with the inverter system. Such a roller system incorporates the use of rollers, and preferably tapered rollers. With both the clamping system and the roller system, each system has the ability to dispense close to the edge of the substrate on both the top and bottom surfaces of the substrate.

With the clamping system, the clamping system is incapable of driving the movement of the substrate onto the clamping system, thereby necessitating the use of the pusher. Without pushers, the belts are capable of moving the substrate about 65% of the way into the dispense position before the belts start slipping thereby preventing the substrate from reaching the dispense position. The pusher and the belts are synchronized and work together to prevent any belt slippage. When the belts start to lose grip on the substrate, the pusher keeps the substrate moving until the substrate is fully delivered to the dispense position within the clamping system of the substrate support assembly. This pusher is configured to lift above the rails since there is a pre-heat chuck in a preheat zone. In a certain embodiment, the upstream pusher is an air cylinder with a finger that contacts the substrate.

Since there are no belts provided in the clamping system, a similar problem arises when removing the substrate from the clamping system. The pusher moves in synchronized motion with downstream conveyor belts. The pusher actually pushes the substrate the whole way so that there is no relative motion between the belts and substrate such that the belts wear away prematurely. This pusher resides under the conveyor so that the pusher can maintain a clear path above the inverter for the dispensing unit. The pusher is also capable of retracting such that the pusher is located beneath the conveyor rails so that the pusher is not in the way when the conveyor starts to move. In a certain embodiment, the downstream pusher is an air cylinder with a finger that contacts the substrate.

The present disclosure is directed to the construction of the clamping system and the pusher and belt assemblies, and addresses the issues involving the limited space that is available in the dispenser for these systems. The inverter system is configured to rotate the substrate once the substrate is secured in the dispense position. In one embodiment, the inverter system is belt driven by a stepper motor, and has a ten-to-one ratio, such that an accurate transport angle is achieved. The complexity of the independent front and rear rail clamp/inverter systems is that they need to be synchronized (spin together without causing any distortion to the substrate). This is achieved by using two different stepper motors with the same pulses coming out of a drive module.

The inverter system is capable of lowering the substrate prior to rotating the substrate while avoiding a collision within the dispense position with the dispensing unit and/or gantry. While rotating a substrate in one lane, the dispensing unit of the dispenser can continue to dispense on a substrate located in an adjacent lane. The inverter system includes linear motion devices having linear bearings, ball screws and stepper motors to drive them. The clamping system is small enough to enable the dispensing unit to get close to the edge of the substrate since there is very little space for the dispensing unit to effectively operate. The clamping system positions the substrate at a dispense height regardless of the orientation and the thickness of the substrate. Clamping members of the clamping system are wide open at a transport height so that the incoming substrate does not get hung up and the clamping system needs to clamp the substrate effectively during rotation of the substrate. The clamping system is configured to be rigid and align tightly in both orientations and at transport and dispense heights.

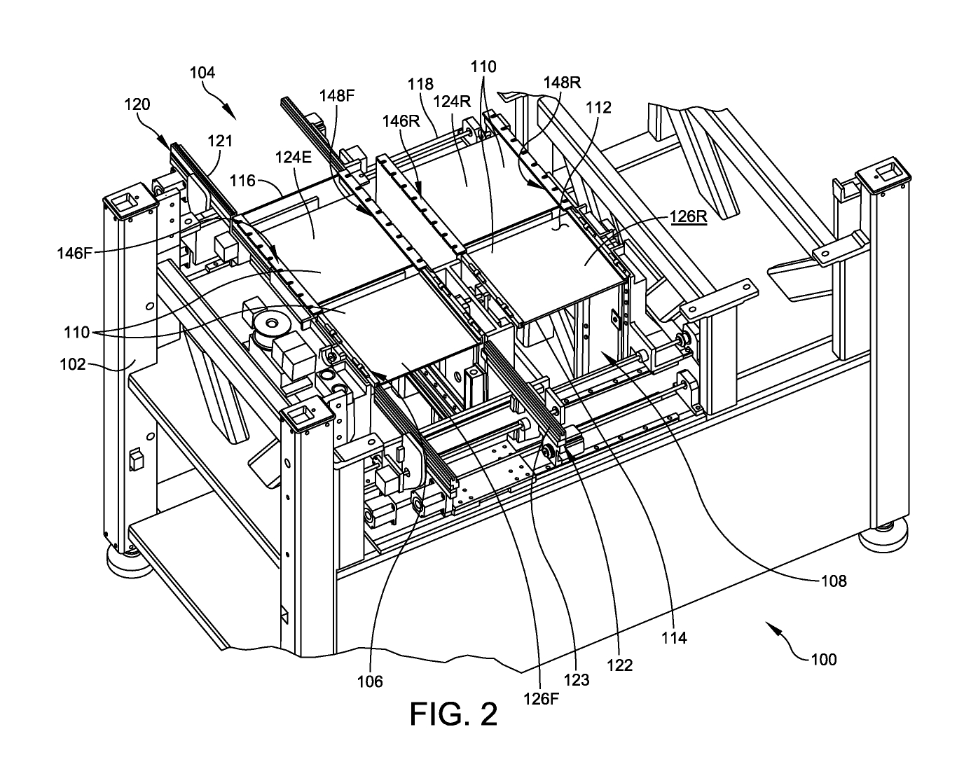

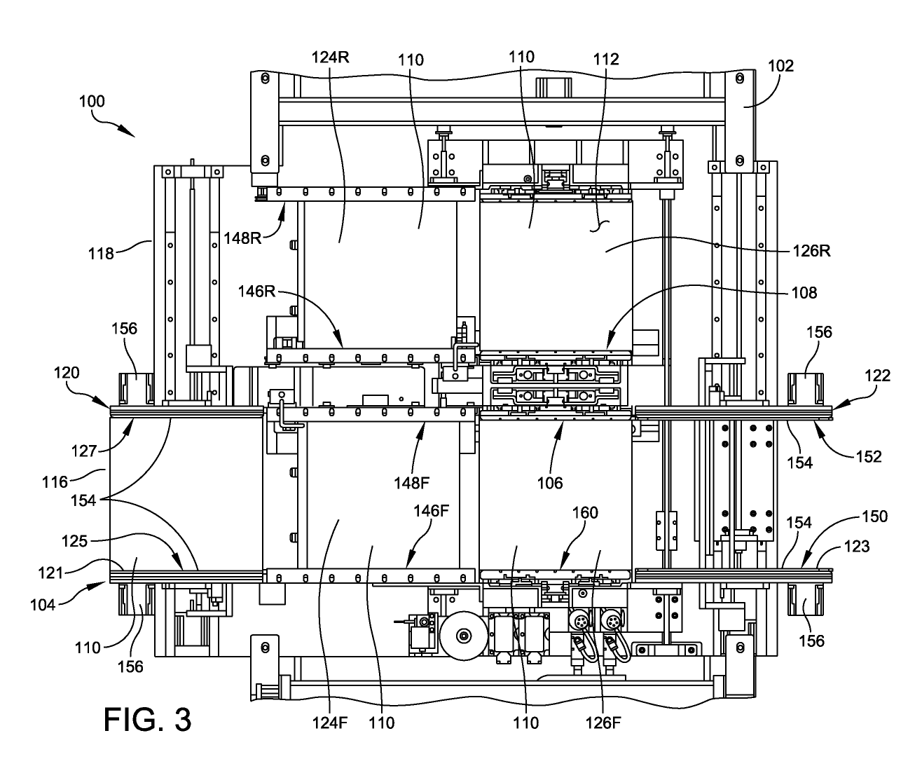

Referring to the drawings, and more particularly to FIGS. 2 and 3, a dispenser of an embodiment of the present disclosure is generally indicated at 100. As shown, the dispenser includes a frame 102, which supports the systems and components of the dispenser, including a transport system generally indicated at 104, which conveys substrates into and out of the dispenser, a clamping system generally indicated at 106, which clamps the substrates during processing, and an inverter system generally indicated at 108, which operates with the clamping system to invert or flip over the substrates to dispense material on both sides of the substrates. Substrates are indicated at 110 throughout the drawings, with a top surface of the substrate being designated at 112 and a bottom surface of the substrate being designated at 114. Each system includes subassemblies that interact with subassemblies of other systems and other components of the dispenser 100 to move substrates 110 into and out of the dispenser and to dispense material on the substrates. A controller associated with the dispenser is configured to control the operation of the systems of the dispenser. In one embodiment, the controller is similar to and provides the functionality of controller 18 of dispenser 10.

FIG. 3 illustrates the frame 102 and the transport system 104 configured to move substrates 110 along two parallel transport paths, a front transport path 116 located toward a front of the dispenser and a rear transport path 118 located toward a rear of the dispenser. The transport system 104 includes a first, upstream conveyor system generally indicated at 120 provided on the left-hand side of the dispenser 100, which is configured to deliver substrates 110 to the front and rear transport paths 116, 118. Specifically, the upstream conveyor system 120 includes a movable conveyor 121, which is configured to move between a first position in which the movable conveyor is aligned with the front transport path 116 and a second position in which the movable conveyor is aligned with the rear transport path 118. FIGS. 2 and 3 show the movable conveyor 121 of the upstream conveyor system 120 in its first position in which the upstream conveyor system is aligned with the front transport path 116. The transport system 104 further includes a second, downstream conveyor system 122 provided on the right-hand side of the dispenser 100, which is configured to remove substrates 110 from the front and rear transport paths 116, 118. As with the upstream conveyor system 120, the downstream conveyor system 122 includes a movable conveyor 123 is configured to move between a first position in which the movable conveyor is aligned with the front transport path 116 and a second position in which the movable conveyor is aligned with the rear transport path 118. FIGS. 2 and 3 show the movable conveyor 123 of the downstream conveyor system 122 in its first position in which the downstream conveyor system is aligned with the front transport path 116.

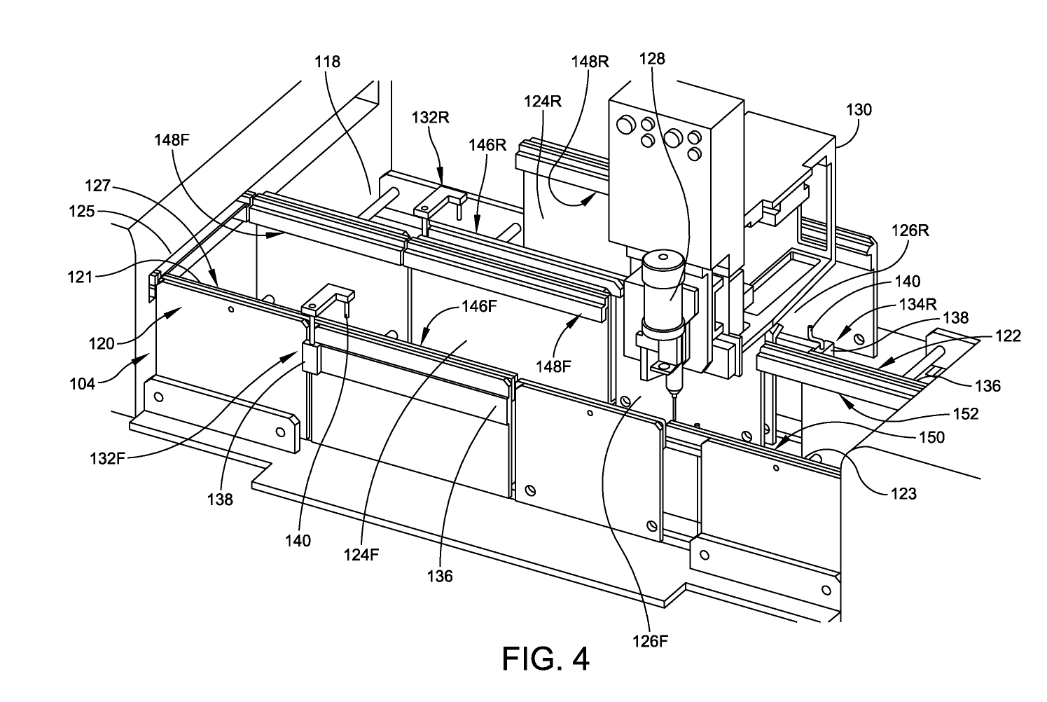

With additional reference to FIG. 4, for each transport path 116, 118, substrates 110 are delivered by the upstream conveyor system 120 from an upstream system, such as a shuttle loader, to a pre-heat position 124F, 124R configured to heat the substrate prior to dispensing. The dispenser 100 includes a pre-heat chuck associated with the front transport path 116 and the rear transport path 118 at the pre-heat positions 124F, 124R. For each transport path 116, 118, the substrates 110 are then moved from the pre-heat position 124F, 124R to a dispense position 126F, 126R in which the substrates are positioned under a dispensing unit 128. The dispensing unit 128 is attached to a dispensing unit gantry 130 to move the dispensing unit in the x-axis, y-axis, and z-axis directions. As will be described in greater detail below, for each of the front transport path 116 and the rear transport path 118, the dispensing unit 128 is capable of dispensing material, such as solder paste, on both sides of the substrate 110, with the clamping system 106 holding the substrate in place during the dispensing operation. After dispensing, the substrates 110 are removed from the dispense position 126F, 126R by the downstream conveyor system 122 to a downstream system, such as a pick-and-place machine or another dispenser.

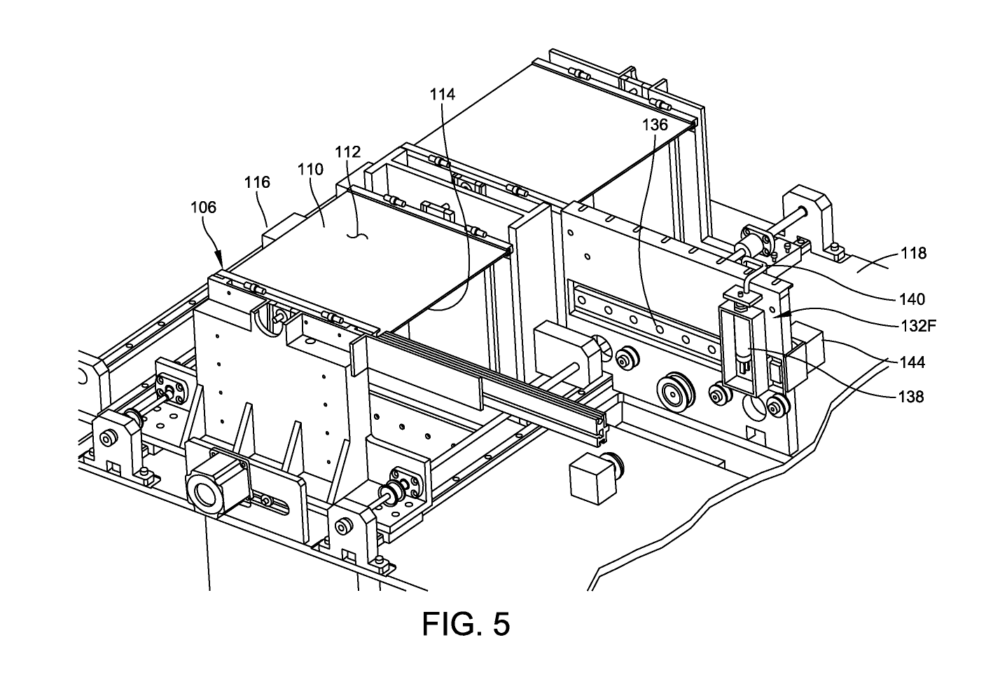

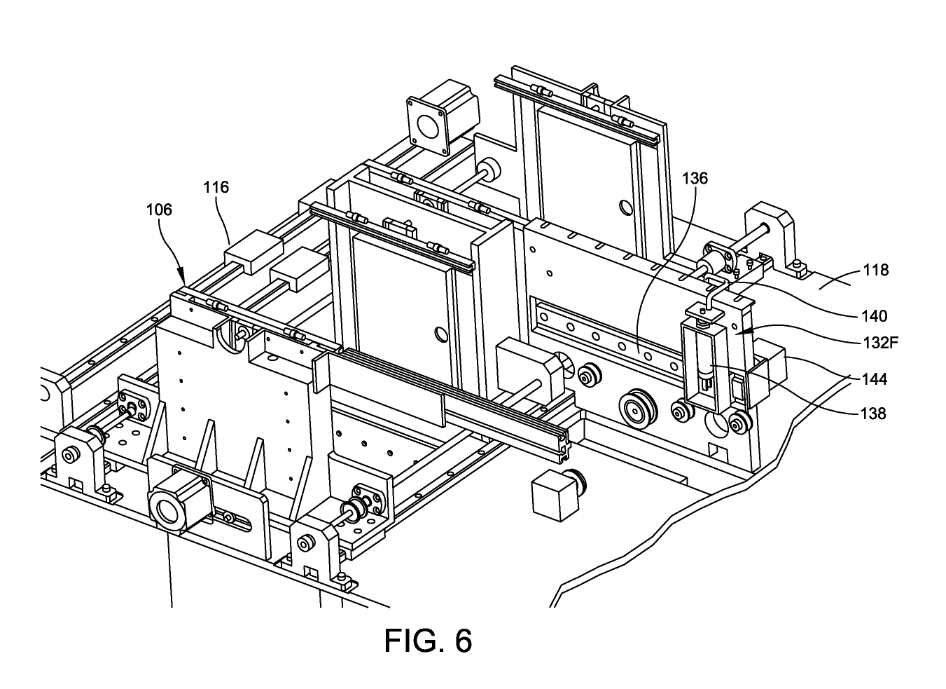

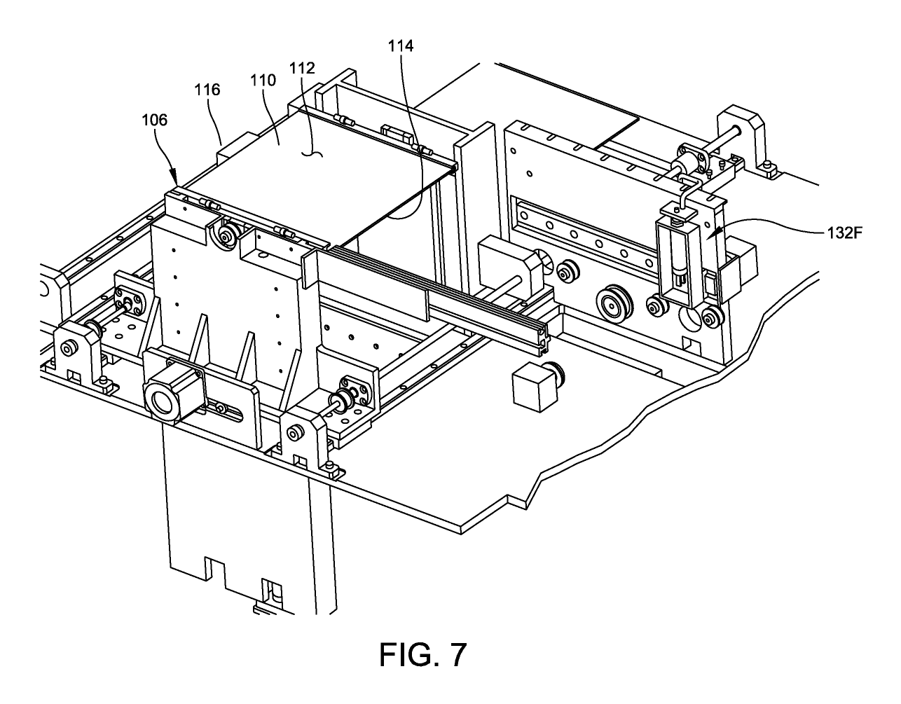

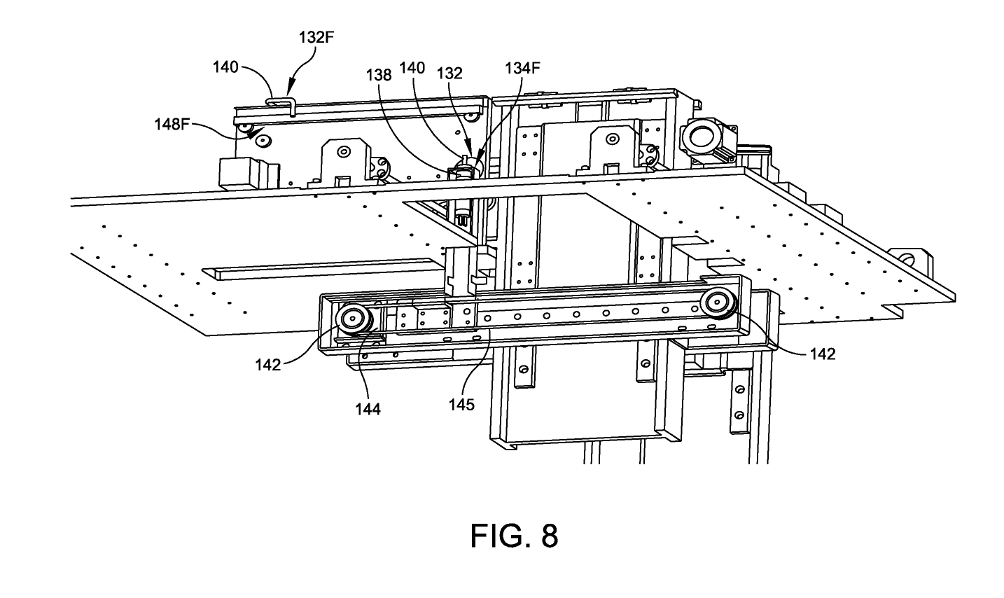

With additional reference to FIGS. 5-8, for each transport path 116, 118, the upstream conveyor system 120 of the transport system 104 is configured to transfer substrates to and from the pre-heat position 124F, 124R and to the dispense position 126F, 126R. The transport system 104 also includes an upstream substrate pusher assembly generally indicated 132F, 132R, which, along with its respective belt assembly to be discussed below, is configured to move the substrate 110 from the pre-heat positions 124F, 124R to the dispense positions 126F, 126R within the dispenser 100. The transport system further includes a downstream substrate pusher assembly generally indicated at 134F, 134R, which is configured to move the substrate from the dispense position to the downstream conveyor, which ultimately will move the substrate to another downstream system, such as another dispenser, or a pick-and-place machine, for example. Although the upstream and downstream pusher assemblies 132, 134 are referred to as “pushers” herein, it should be observed that these components could also be referred to as “pullers” since they also can be configured with grippers to pull the substrates as well, and fall within the scope of the present disclosure. Each pusher assembly 132, 134 employs a linear bearing 136 to move an air cylinder 138 having a pusher member 140 from left to right along the transport path, and is controlled by a belt drive having pulleys each indicated at 142 with a motor 144 provided to drive a belt 145, which rides on the pulleys. The air cylinder 138 for the downstream pusher member 140 extends up from below the substrate to move the substrate. For the downstream pusher assembly 134, the pusher member 140 parks under the downstream conveyor system 122 during an inversion process described below to clear the way for the clamping system 106 to spin 180 degrees.

As shown in the drawings, for each transport path 116, 118, the upstream conveyor system 120 of the transport system 104 includes a belt assembly generally indicated at 125 provided along one side of the upstream conveyor system and another belt assembly generally indicated at 127 provided along an opposite side of the upstream conveyor system. These belt assemblies 125, 127 are configured to drive the movement of the substrate 110 into the pre-heat position. The upstream pusher assembly 132 is configured to work in conjunction with the preheat belts 146, 148 to deliver the substrate from the pre-heat position 124 to the dispense position 126. As shown in FIG. 3, the pre-heat position 124F of the front lane 116 includes belt assemblies 146F, 148F and the pre-heat position 124R of the rear lane 118 includes belt assemblies 146R, 148R.

For each transport path 116, 118, the downstream conveyor system 122 of the transport system 104 includes a belt assembly generally indicated at 150 provided along one side of the downstream conveyor system and another belt assembly generally indicated at 152 provided along an opposite side of the downstream conveyor system. Once a dispensing operation takes place on the substrate 110 (on the top surface 112 and/or the bottom surface 114 of the substrate), the downstream pusher assembly 134, along with the belt assembly 150, 152, removes the substrate from the dispensing position 126 for the downstream conveyor system to later completely remove the substrate from the dispenser 100.

For each belt assembly 125, 127, 150, 152, the belt assembly includes a belt each indicated at 154 driven by a motor 156 and configured to engage an edge of the substrate 110, and another belt driven by another motor and configured to engage an opposite edge of the substrate. As mentioned above, each pusher assembly 132, 134 includes a pusher member 140 configured to engage an edge of the substrate 110 to move the substrate along the transport path 116 or 118. Each pusher assembly 132, 134 includes a guide member (linear bearing 136 and air cylinder 138 assembly as described above) coupled to the pusher member 140 and configured to guide a linear movement of the pusher member, with the motor 144 being configured to move the pusher member. Each of the pusher assemblies 132, 134 are synchronized with their respective belt assembly 146, 148, 150, 152 to maintain a constant velocity during delivery of the substrate to and from the dispense position 126.

In a certain embodiment, the movement of substrates 110 through the dispenser 100 may proceed as follows. The movable conveyor 121 of the upstream conveyor system 120 receives a first substrate 110 and is moved to the first position to deliver the substrate to the front transport path 116. This substrate is moved by the transport system 104 to the pre-heat position 124F by the belt assemblies 125, 127 of the upstream conveyor system 120 and belt assemblies 146F, 148F of the transport system. The substrate 110 is then moved from the pre-heat position 124F to the dispense position 126F by the belt assemblies 146F, 148F associated with the pre-heat assembly and the upstream pusher assembly 132F, which is moved to maintain a constant velocity during delivery of the substrate to the dispense position 126F.

Once in the dispense position 126F associated with the front transport path 116, a dispense operation takes place on the top surface 112 of the substrate 110 with the dispensing unit 128. After dispensing on the top surface 112, the substrate 110 may be inverted to perform a dispense operation on the bottom surface 114 of the substrate. When the dispense operation is completed, the substrate 110 is removed from the dispense position 126F by the downstream pusher assembly 134F associated with the downstream conveyor system 122, which includes belt assemblies 150, 152, to deliver the substrate to the downstream system. The downstream pusher assembly 134F is synchronized with its respective belt assemblies 150, 152 of the downstream conveyor system 122 to maintain a constant velocity during delivery of the substrate to the downstream conveyor system. The substrate 110 is delivered to the movable conveyor 123 of the downstream conveyor system 122.

After the first substrate is delivered to the dispenser 100 and moved to the dispense position 126F, the movable conveyor 121 of the upstream conveyor system 120 receives a second substrate 110 and is moved to the second position to deliver the substrate to the rear transport path 118. This second substrate is moved by the transport system 104 to pre-heat and dispense positions 124R, 126R by the belt assemblies 125, 127 of the upstream conveyor system 120 and the upstream pusher assembly 132R associated with the rear transport path 118 of the transport system. Once in the dispense position 126R associated with the rear transport path 118, a dispense operation takes place on the top surface 112 of the substrate. After dispensing on the top surface 112, the substrate may be inverted to perform a dispense operation on the bottom surface 114 of the substrate. When the dispense operation is completed, the substrate is removed from the dispense position 126R by the downstream pusher assembly 134R associated with the downstream conveyor system 122, which includes belt assemblies 150, 152, to deliver the substrate to the downstream system. The downstream pusher assembly 134R is synchronized with its respective belt assemblies 150, 152 of the downstream conveyor system 122 to maintain a constant velocity during delivery of the second substrate to the downstream conveyor system. The substrate 110 is delivered to the movable conveyor 123 of the downstream conveyor system 122.

The process repeats itself with the movable conveyor 121 of the upstream conveyor system 120 alternating between its first and second positions to deliver substrates 110 to the front transport path 116 and the rear transport path 118, respectively. The dispenser 100 may be configured to dispense on the top surface 112 and/or bottom surface 114 of the substrate 110 once the substrate is delivered to the dispense position 126 within its respective transport path 116 or 118.

It should be observed that the transport system 104 described herein may be used in other applications requiring the transportation of substrates. For example, the transport system may be used in stencil printers, reflow ovens, wave soldering machines, and pick-and-place machines.

As discussed above, the foregoing operations may be controlled by a controller, such as controller 18 referenced with dispenser 10.

Having thus described at least one embodiment of the disclosure, various alternations, modifications and improvements will readily occur to those skilled in the art. Such alterations, modifications and improvements are intended to be within the scope and spirit of the disclosure. Accordingly, the foregoing description is by way of example only and is not intended to be limiting. The limit is defined only in the following claims and equivalents thereto.

What is claimed is:

1. A dispenser for dispensing viscous material on a substrate, the dispenser comprising:
a frame;
a gantry system coupled to the frame;
a dispensing unit coupled to the gantry system, the gantry system being configured to move the dispensing unit in x-axis, y-axis, and z-axis directions; and
a substrate support assembly coupled to the frame and configured to support the substrate to dispense material on the substrate in a dispense position;
a transport system configured to transport the substrate to the dispense position and to remove the substrate from the dispense position, the transport system including a first pusher assembly configured to move the substrate within the dispenser.

2. The dispenser of claim 1, wherein the first pusher assembly includes a pusher member configured to engage an edge of the substrate, a linear bearing configured to guide a linear movement of the pusher member, and a motor configured to move the pusher member.

3. The dispenser of claim 1, wherein the transport system further includes a first belt assembly configured to operate with the first pusher assembly to move the substrate within the dispenser.

4. The dispenser of claim 3, wherein the first belt assembly includes a first belt configured to engage an edge of the substrate, a second belt configured to engage an opposite edge of the substrate, and at least one motor configured to drive the rotation of the first belt and the second belt.

5. The dispenser of claim 4, wherein the first pusher assembly is synchronized with a respective belt assembly to maintain a constant velocity during delivery of the substrate to and from the dispense position.

6. The dispenser of claim 1, wherein the transport system further includes a second pusher assembly to move the substrate.

7. The dispenser of claim 6, wherein each of the first pusher assembly and the second pusher assembly includes a pusher member configured to engage an edge of the substrate, a linear bearing configured to guide a linear movement of the pusher member, and a motor configured to move the pusher member.

8. A transport system for a dispenser for dispensing viscous material on a substrate, the transport system being configured to transport the substrate to a dispense position of the dispenser and to remove the substrate from the dispense position, the transport system comprising:
a first pusher assembly configured to move the substrate within the dispenser.

9. The transport system of claim 8, further comprising a first belt assembly configured to operate with the first pusher assembly to move the substrate within the dispenser.

10. The transport system of claim 9, wherein the first belt assembly includes a first belt configured to engage an edge of the substrate, a second belt configured to engage an opposite edge of the substrate, and at least one first motor configured to drive the rotation of the first belt and the second belt.

11. The transport system of claim 10, wherein the first pusher assembly is synchronized with a respective belt assembly to maintain a constant velocity during delivery of the substrate to the dispense position.

12. The transport system of claim 8, further comprising a second pusher assembly configured to move the substrate.

13. The transport system of claim 12, wherein each of the first pusher assembly and the second pusher assembly includes a pusher member configured to engage an edge of the substrate, a linear bearing configured to guide a linear movement of the pusher member, and a motor configured to move the pusher member.

14. A method of transporting a substrate within a dispenser, the method comprising:
moving the substrate within the dispenser with a first pusher assembly configured to move the substrate.

15. The method of claim 14, wherein moving the substrate within the dispenser further includes engaging a first belt assembly with the substrate.

16. The method of claim 15, wherein engaging the first belt assembly with the substrate includes engaging a first belt with an edge of the substrate, and engaging a second belt with an opposite edge of the substrate.

17. The method of claim 16, wherein the first pusher assembly is synchronized with a respective belt assembly to maintain a constant velocity during delivery of the substrate within the dispenser.

18. The method of claim 17, further comprising driving the rotation of the first belt and the second belt with at least one first motor.

19. The method of claim 14, further comprising moving the substrate within the dispenser with a second pusher assembly configured to move the substrate.
